(19) United States
(12) Patent Application Publication
(10) Pub. No.: US 2013/0063275 A1
(43) Pub. Date: Mar. 14, 2013

(54) Dual Strobe Expander Plate

(71) Applicant: Thomas J. Kucala, Cortland, IL (US)

(72) Inventor: Thomas J. Kucala, Cortland, IL (US)

(73) Assignee: Honeywell International Inc., Morristown, NJ (US)

(21) Appl. No.: 13/230,008

(22) Filed: Sep. 12, 2011

(51) Int. Cl. G08B 5/00; H05K 7/00; F21V 21/00

(52) U.S. Cl. 340/815.4; 362/382; 361/679.01

(57) ABSTRACT

An output device mounting plate can in a disclosed embodiment carry a fixedly mounted strobe unit with a displaced region to releasibly attach additional output devices. The devices can include a verbal output device, an audible output device, a visual output device, or an audible/visual output device.

### FIELD

The application pertains to mounting elements usable with alarm indicating output devices. More particularly, it pertains to such elements which can support a variable plurality of such output devices.

### BACKGROUND

Regional monitoring systems, such as such as fire alarm or regional security systems often include various types of alarm indicating output devices. These include audible or visual devices. Some of these types of devices are mandated by governmental codes. Others respond to customer or installation needs.

Customer, or installation needs can be best addressed by providing flexible mounting systems which can not only meet current known needs, but which can address future changing needs for types, or combinations of output devices.

### BRIEF DESCRIPTION OF THE DRAWINGS

FIG. 1 is an exploded view illustrating aspects of a mounting element in accordance herewith;

FIG. 2A is a front view of a mounting element as in FIG. 1;

FIG. 2B is a front view of a different mounting element;

FIG. 3 is an exploded view illustrating installation of one output device combination; and

FIG. 4 is an exploded view illustrating installation of a different device combination.

### DETAILED DESCRIPTION

While disclosed embodiments can take many different forms, specific embodiments thereof are shown in the drawings and will be described herein in detail with the understanding that the present disclosure is to be considered as an exemplification of the principles thereof as well as the best mode of practicing same, and is not intended to limit the application or claims to the specific embodiment illustrated.

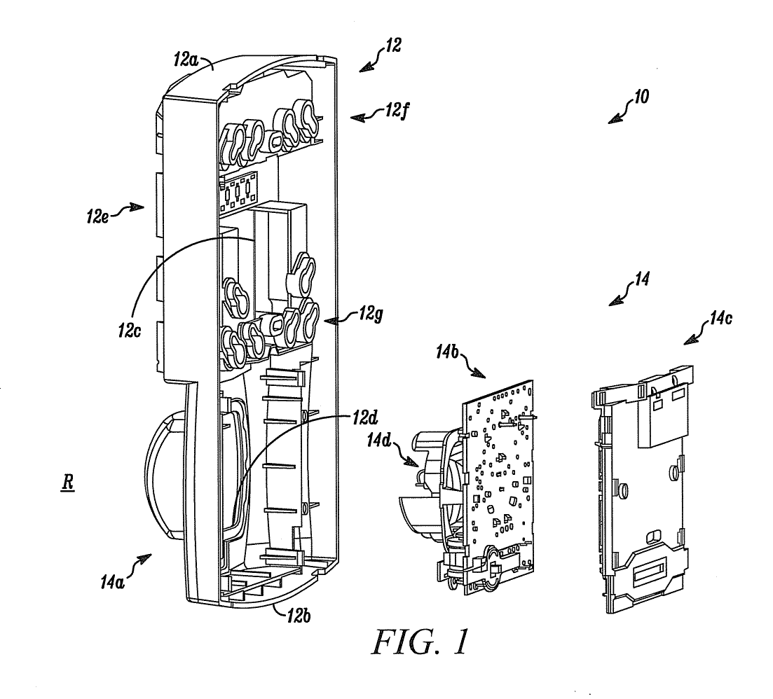

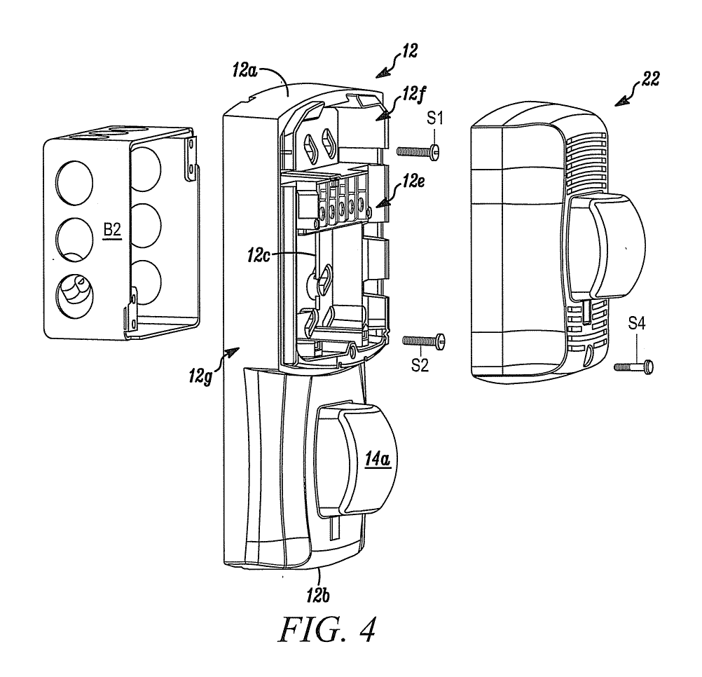

FIG. 1 illustrates an apparatus 10 having a multiple output device, elongated mounting plate 12 and carrying a fixedly attached strobe unit 14. Plate 12 is mountable on or in close proximity to an electrical box, best seen in FIG. 4. Plate 12 is elongated with first and second ends 12a, 12b. The plate 12 defines an upper opening 12c and a lower opening 12d.

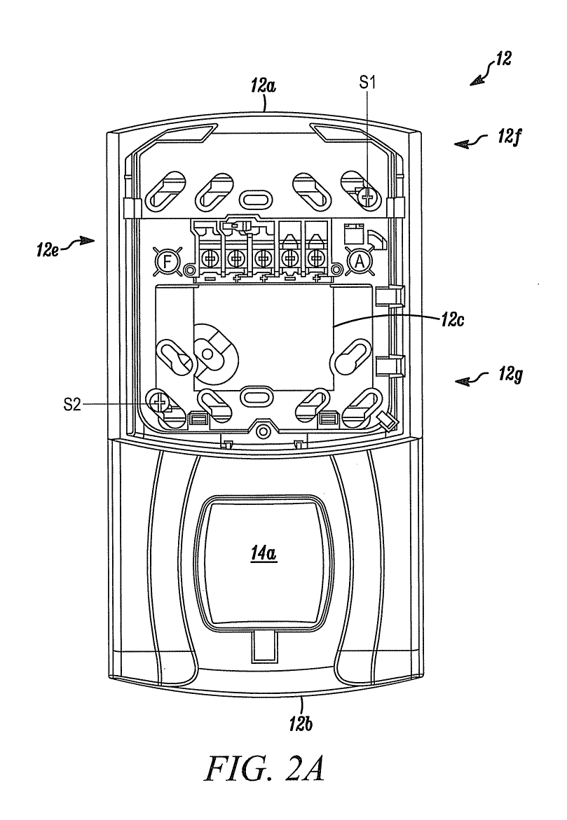

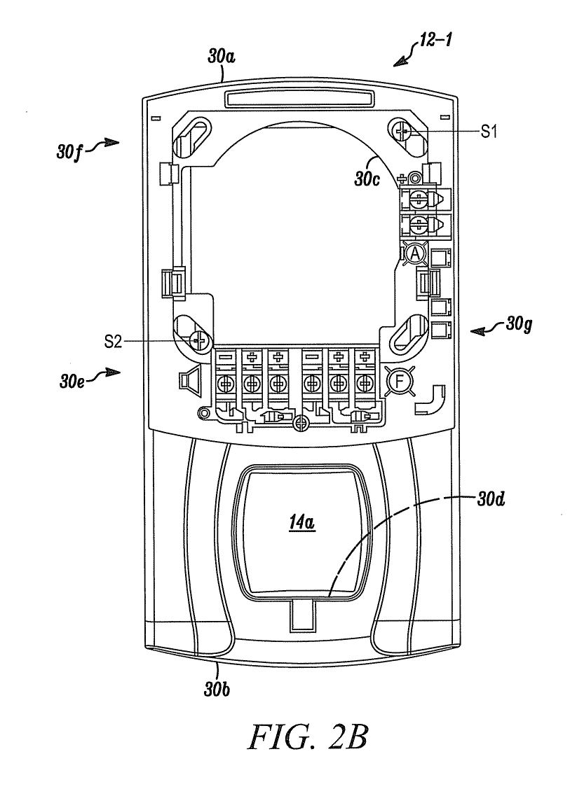

Plate 12 includes a plurality of electrical connectors, 12e, best seen in FIG. 2A, and FIG. 4. Electrical wiring, coupled to an associated alarm system, extends into the associated electrical box, best seen in FIG. 4, pairs W1, W2. The wires can be connected to selected ones of the connectors 12e to energize the output units carried by the plate 12. As those of skill in the art will understand, the electrical signals coupled to the connectors 12e can be modulated to convey commands, addresses or the like.

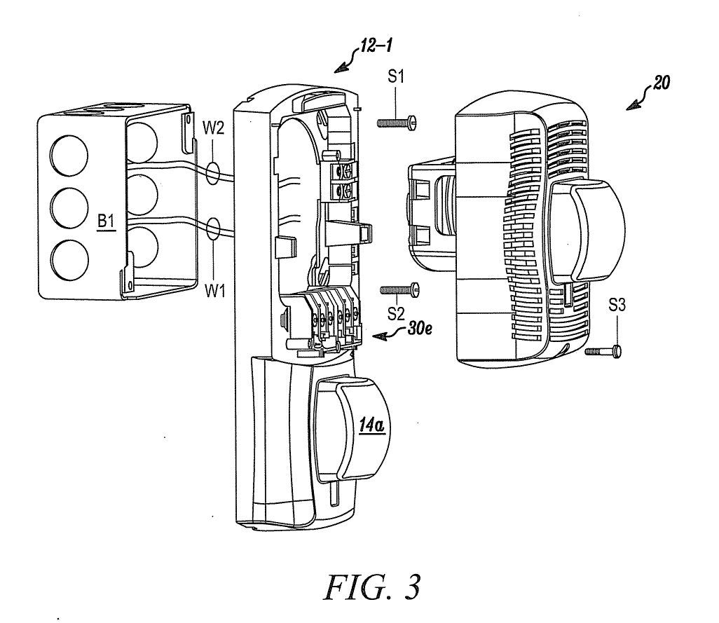

Mechanical attachment features, 12f,g carried on plate 12 can receive screws or other fasteners such as S1, S2 to attach the plate 12 to the respective electrical box, such as B1, or B2. Also, a best seen in FIGS. 3,4 the attachment plates, such as plate 12 are longer than are the respective electrical boxes B1, B2 to be able to carry multiple output devices.

Device 14, illustrated for exemplary purposes as a strobe has a lens 14a, attached to the respective plate such as plate 12, a body portion which carries the electronics and flash tube module 14b, and a backplate 14c. As illustrated in FIG. 1, the electronics and flash tube module 14b are sandwiched between the lens 14a and backplate 14c. Backplate 14c is coupled to plate 12 with a friction or snap fit. Adhesive or ultrasonic welding can also be used. It will also be understood, that in an alternate embodiment, strobe 14 could also be field installable and changeable.

Electrical conductors extend between selected of the connectors 12e and the module 14b to energize and flash the associated flash tube 14d. The strobe unit 14, and lens 14a can be used to indicate an alert condition, for example that a region R being monitored by the associated monitoring system should be evacuated. Hence, lens 14a can be of a selected alert indicating color, not one associated with a fire condition, for example.

Members 20, 22 of a plurality of alarm indicating output devices, see FIGS. 3, 4 can be removably coupled to the illustrated mounting plates 12, 12-1. The members 20, 22 can be selected from a class which includes at least verbal output devices, audible output devices, visual output devices, or audio/visual output devices, all without limitation.

The members 20, 22 have a form-factor, including electrical connectors that slidably engage respective portions of the appropriate mounting plate 12, 12-1. It will be understood that none of the exact details of the output devices 20, 22 are limitations hereof, other than as set forth herein. Hence, as the interchangeable output devices are mounted on the respective mounting plate 12. 12-1 they slidably engage respective of the connectors 12e to be able to receive electrical energy therefrom when connected with the pairs of wires in the box, such as B1, B2. The respective output devices can be attached to the respective plate 12, 12-1 by a fastener, such as screw S3, S4. It will also be understood the output devices 20, 22 are field installable and could be replaced, or changed, after initial installation, unlike the fixedly mounted units 14.

FIGS. 2B and 3 illustrate an alternate form of a multiple output device, elongated mounting plate 12-1 which also carries a fixedly attached strobe unit 14. Plate 12-1 is mountable on or in close proximity to an electrical box, best seen in FIG. 3. Plate 12-1 is elongated with first and second ends 30a, 30b. The plate 12-1 defines an upper opening 30c and a lower opening 30d.

Plate 12-1 includes a plurality of electrical connectors, 30e, best seen in FIG. 2B, and FIG. 3. Electrical wiring, coupled to an associated alarm system, extends into the associated electrical box, best seen in FIG. 4, pairs W1, W2. The wires can be connected to selected ones of the connectors 30e to energize the output units carried by the plate 12-1. As those of skill in the art will understand, the electrical signals coupled to the connectors 30e can be modulated to convey commands, addresses or the like.

Mechanical attachment features, 30f, g carried on plate 12-1 can receive screws or other fasteners such as S1, S2 to attach the plate 12-1 to the respective electrical box, such as B1, or B2. Also, a best seen in FIGS. 3, 4 the attachment plates, such as plate 12-1 are longer than are the respective electrical boxes B1, B2 to be able to carry multiple output devices.

Other variations come within the spirit and scope hereof. For example, where the boxes, such as B1, B2 are surface mounted, a back box skirt can be interposed between the wall and the respective expander, or mounting, plate, such as 12, 12-1.

From the foregoing, it will be observed that numerous variations and modifications may be effected without departing from the spirit and scope of the invention. It is to be understood that no limitation with respect to the specific apparatus illustrated herein is intended or should be inferred. It is, of course, intended to cover by the appended claims all such modifications as fall within the scope of the claims. Further, logic flows depicted in the figures do not require the particular order shown, or sequential order, to achieve desirable results. Other steps may be provided, or steps may be eliminated, from the described flows, and other components may be add to, or removed from the described embodiments.

1. An apparatus comprising:
an elongated mounting plate, the plate having first and second ends and carrying a first plurality of electrical connectors engagable with a source of electrical energy, the plate carrying a fixedly mounted strobe unit; and
where the mounting plate defines an attachable module receiving section.

2. An apparatus as in claim 1 where the attachable module receiving section carries a second plurality of electrical connectors and where members of a third plurality of electrical connectors of a selected module mate with members of the second plurality.

3. An apparatus as in claim 1 which includes a plurality of different, attachable modules with each of the modules indicating a predetermined condition.

4. An apparatus as in claim 3 where the attachable module receiving section carries a second plurality of electrical connectors and where each member of the plurality carries a third plurality of electrical connectors the members of the third plurality of a selected module mate with members of the second plurality when the selected module is installed on the module receiving section.

5. An apparatus as in claim 4 where the modules are selected from a class which includes at least a verbal output module, an audio output module, a visual output module, and an audible/visual output module.

6. An apparatus as in claim 4 where each of the modules carries an attachment element mechanically attaching the respective module to the plate.

7. An apparatus as in claim 4 where the receiving section of the plate defines an interior open region.

8. An apparatus as in claim 2 where the plate includes an electrical box attachment structure.

9. An apparatus as in claim 8 where the plate extends from a respective electrical box in an elongated direction.

10. An apparatus as in claim 7 where the strobe unit is carried at an end of the plate.

11. An apparatus as in claim 10 where the replaceable module is carried at the other end of the plate.

12. A mounting plate comprising:
an elongated body having first and second spaced apart openings therethrough;
electrical input connectors carried on the body;
at least one attachment element carried on the body located near one of the openings;
a different attachment element carried on the body located near the other opening;
electrical distribution elements carried on the body located near the one opening; and
a replaceable module electrical connection carried on the body located near the other opening.

13. A mounting plate as in claim 12 where one of the openings is closed with a lens.

14. A mounting plate as in claim 13 where a strobe unit is mounted behind the lens.

15. A mounting plate as in claim 13 where a backplate is attached to the mounting plate extending along a substantially planar side of the strobe unit with the strobe unit sandwiched between the backplate and the lens.

16. A mounting plate as in claim 15 where electrical conductors couple the strobe unit to the electrical input connectors.

17. A mounting plate as in claim 16 where the backplate is attached to the body with at least one of adhesive, a snap fit, or a friction fit.
